(19) United States
(12) Patent Application Publication
(10) Pub. No.: US 2025/0294996 A1
(43) Pub. Date: Sep. 18, 2025

(54) DISPLAY APPARATUS

(71) Applicant: SAMSUNG DISPLAY CO., LTD., Yongin-si (KR)

(72) Inventors: Minsoo CHOI, Yongin-si (KR); Jinsoo JUNG, Yongin-si (KR); Seokgyu YOON, Yongin-si (KR)

(21) Appl. No.: 19/025,393

(22) Filed: Jan. 16, 2025

(30) Foreign Application Priority Data
Mar. 14, 2024 (KR) 10-2024-0035983

(51) Int. Cl. H10K 59/60; H10K 59/38; H10K 59/80; H10K 101/60

(52) U.S. Cl. CPC H10K 59/60; H10K 59/38; H10K 59/80522; H10K 2101/60

(57) ABSTRACT

A display apparatus includes: a substrate including an emission area and a sensing area; a light-emitting device disposed on the substrate to correspond to the emission area; a light-receiving device disposed on the substrate to correspond to the sensing area; and an upconversion device covering the light-receiving device.

### CROSS-REFERENCE TO RELATED APPLICATION

This application claims priority under 35 U.S.C. § 119 to Korean Patent Application No. 10-2024-0035983, filed on Mar. 14, 2024, in the Korean Intellectual Property Office, the disclosure of which is incorporated by reference herein in its entirety.

### TECHNICAL FIELD

One or more embodiments of the present invention relate to the structure of a display apparatus.

### DISCUSSION OF THE RELATED ART

In general, a display apparatus includes a light-emitting device, such as an organic light-emitting diode, and a thin-film transistor that is disposed on a substrate and operates by causing light-emitting devices to emit light.

For example, each pixel of the display apparatus has a light-emitting device, such as an organic light-emitting diode, in which an intermediate layer including an emission layer is arranged between a pixel electrode and a counter electrode. In the display apparatus, whether or not to emit light or the degree of light emission of each pixel is generally controlled through the thin-film transistor that is electrically connected to the pixel electrode. Some layers included in the intermediate layer of the light-emitting device may be commonly provided for a plurality of light-emitting devices.

### SUMMARY

According to an embodiment of the present invention, a display apparatus includes: a substrate including an emission area and a sensing area; a light-emitting device disposed on the substrate to correspond to the emission area; a light-receiving device disposed on the substrate to correspond to the sensing area; and an upconversion device covering the light-receiving device.

In an embodiment of the present invention, the upconversion device is configured to convert light in a first wavelength band into light in a second wavelength band and emit the converted light, wherein the upconversion device is configured to receive the light in the first wavelength band from outside, and the light in the second wavelength band has a shorter wavelength than the light in the first wavelength band.

In an embodiment of the present invention, the upconversion device is further configured to convert light in a near-infrared wavelength band into light in a visible light wavelength band and emit the converted light, wherein the upconversion device is configured to receive the light in the near-infrared wavelength band from the outside.

In an embodiment of the present invention, the light-receiving device includes: a sensing electrode; an active layer disposed on the sensing electrode; and a counter electrode disposed on the active layer.

In an embodiment of the present invention, the light-emitting device includes: a pixel electrode; an emission layer disposed on the pixel electrode; and a counter electrode disposed on the emission layer.

In an embodiment of the present invention, the counter electrode of the light-receiving device and the counter electrode of the light-emitting device are formed as a single body on the substrate.

In an embodiment of the present invention, the upconversion device includes: a lower auxiliary electrode disposed on the counter electrode; an auxiliary intermediate layer disposed on the lower auxiliary electrode; and an upper auxiliary electrode disposed on the auxiliary intermediate layer.

In an embodiment of the present invention, the auxiliary intermediate layer includes: an auxiliary emission layer disposed on the lower auxiliary electrode; and an auxiliary active layer disposed on the auxiliary emission layer.

In an embodiment of the present invention, the display apparatus further includes a capping layer that is arranged between the counter electrode and the lower auxiliary electrode.

In an embodiment of the present invention, the upconversion device includes: an auxiliary intermediate layer disposed on the counter electrode; and an upper auxiliary electrode disposed on the auxiliary intermediate layer.

In an embodiment of the present invention, the auxiliary intermediate layer includes: an auxiliary emission layer disposed on the counter electrode; and an auxiliary active layer disposed on the auxiliary emission layer.

In an embodiment of the present invention, an upper surface of the counter electrode and a lower surface of the auxiliary intermediate layer are in contact with each other.

In an embodiment of the present invention, the counter electrode of the light-receiving device is also used as a lower auxiliary electrode of the upconversion device.

In an embodiment of the present invention, the display apparatus further includes a thin-film encapsulation layer disposed on the light-emitting device and the upconversion device.

According to an embodiment of the present invention, a display apparatus includes: a substrate; a light-emitting device disposed on the substrate and including a pixel electrode, an emission layer disposed on the pixel electrode, and a counter electrode disposed on the emission layer; a light-receiving device disposed on the substrate and including a sensing electrode, an active layer disposed on the sensing electrode, and a counter electrode disposed on the active layer; and an upconversion device overlapping the light-receiving device and including an auxiliary intermediate layer and an upper auxiliary electrode disposed on the auxiliary intermediate layer.

In an embodiment of the present invention, the upconversion device is configured to convert light in a first wavelength band into light in a second wavelength band and emit the converted light, wherein the upconversion device is configured to receive the light in the first wavelength band from outside, and the light in the second wavelength band has a shorter wavelength than the light in the first wavelength band.

In an embodiment of the present invention, the auxiliary intermediate layer includes: an auxiliary emission layer disposed on the light-receiving device; and an auxiliary active layer disposed on the auxiliary emission layer.

In an embodiment of the present invention, the upconversion device further includes a lower auxiliary electrode that is arranged between the counter electrode of the light-receiving device and the auxiliary intermediate layer.

In an embodiment of the present invention, the display apparatus further includes a capping layer that is arranged between the counter electrode of the light-receiving device and the lower auxiliary electrode.

In an embodiment of the present invention, an upper surface of the counter electrode of the light-receiving device and a lower surface of the auxiliary intermediate layer are in contact with each other.

In an embodiment of the present invention, the counter electrode of the light-receiving device is commonly used in the light-receiving device and the upconversion device.

### BRIEF DESCRIPTION OF THE DRAWINGS

The above and other aspects and features of embodiments of the present invention will be more apparent by describing in detail embodiments thereof, with reference to the accompanying drawings, in which:

FIG. 1 is a schematic plan view of a portion of a display apparatus according to an embodiment of the present invention;

FIGS. 2A and 2B are each a schematic cross-sectional view of a display apparatus according to an embodiment of the present invention;

FIG. 3 is a circuit diagram of a pixel circuit, which is electrically connected to a light-emitting device of a display apparatus, and a sensor circuit, which is electrically connected to a light-receiving device of the display apparatus, according to an embodiment of the present invention;

FIG. 4 is a schematic plan view of a portion of a display apparatus according to an embodiment of the present invention;

FIG. 5 is a schematic cross-sectional view of a portion of a display apparatus according to an embodiment of the present invention;

FIG. 6 is a schematic conceptual diagram of a portion of a display apparatus according to an embodiment of the present invention; and

FIG. 7 is a schematic cross-sectional view of a portion of a display apparatus according to an embodiment of the present invention.

FIG. 8 is a block diagram of an electronic apparatus according to an embodiment of the present invention.

FIG. 9 is a schematic diagrams of electronic apparatuses according to various embodiments.

### DETAILED DESCRIPTION OF THE EMBODIMENTS

Embodiments of the present invention will now be described more fully with reference to the accompanying drawings. It is to be understood that the present invention may be embodied in different forms and thus should not be construed as being limited to the embodiments set forth herein. It is to be understood that like reference numerals may refer to like elements throughout the specification, and thus, redundant descriptions may be omitted. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present invention.

It will be understood that the singular forms include the plural forms unless the context clearly indicates otherwise.

It will be understood that when an element or layer is referred to as being “on” another element or layer, the element or layer may be directly on another element or layer or intervening elements or layers.

In the drawings, various thicknesses, lengths, and angles are shown and while the arrangement shown does indeed represent an embodiment of the present invention, it is to be understood that modifications of the various thicknesses, lengths, and angles may be possible within the spirit and scope of the present invention and the present invention is not necessarily limited to the particular thicknesses, lengths, and angles shown.

When an embodiment may be implemented differently, a certain process order may be performed differently from the described order. For example, two consecutively described processes may be performed substantially at the same time or performed in an order opposite to the described order.

In the following embodiments, when a layer, region, or element is referred to as being “connected to” another layer, region, or element, it can be directly or indirectly connected to the other layer, region, or element. That is, for example, when a layer, region, or element is indirectly connected to another layer, region, or element, intervening layers, regions, or elements may be present. For example, when a layer, region, or element is referred to as being “electrically connected to” another layer, region, or element, it can be directly or indirectly electrically connected to the other layer, region, or element. That is, for example, when a layer, region, or element is indirectly electrically connected to the other layer, region, or element, intervening layers, regions, or elements may be present.

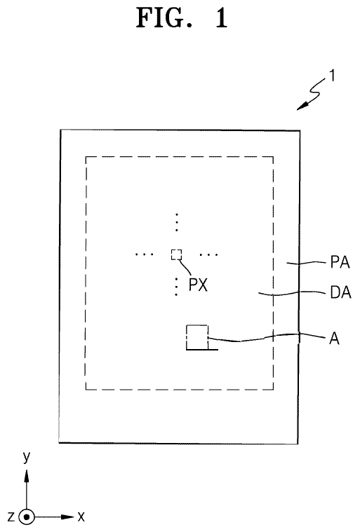

FIG. 1 is a schematic plan view of a portion of a display apparatus 1 according to an embodiment of the present invention.

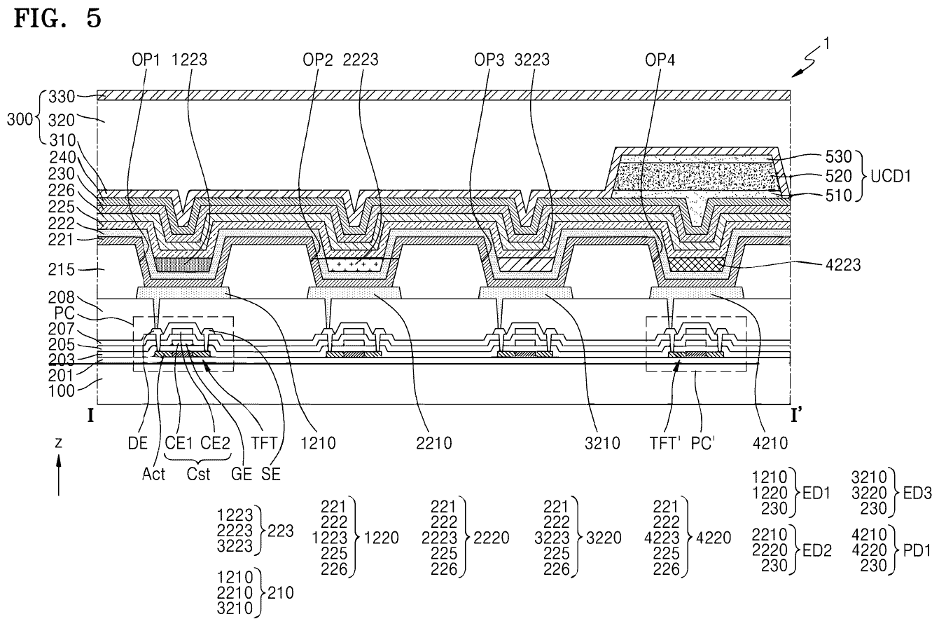

Referring to FIG. 1, the display apparatus 1 may include a display area DA in which a plurality of pixels PX are arranged and a peripheral area PA located outside the display area DA. For example, the peripheral area PA may entirely surround the display area DA. The above may be understood as meaning that a substrate 100 (see FIG. 5) included in the display apparatus 1 has the display area DA and the peripheral area PA.

Each pixel PX of the display apparatus 1 refers to a minimum unit for displaying an image, and the display apparatus 1 may display a desired image through a combination of the plurality of pixels PX. For example, each pixel PX may emit light of a certain color, and the display apparatus 1 may display a desired image by using light emitted from the pixels PX. For example, each pixel PX may emit red light, green light, or blue light. Each pixel PX may include a light-emitting device, such as an organic light-emitting diode. The pixel PX may be connected to a pixel circuit including a thin-film transistor, a storage capacitor, and the like.

As shown in FIG. 1, the display area DA may have a polygonal shape including a quadrangular shape. For example, the display area DA may have a rectangular shape having a horizontal length greater than a vertical length, a rectangular shape having a horizontal length less than a vertical length, or a square shape. In addition, the display area DA may have various shapes, such as an oval shape or a circular shape.

The peripheral area PA may be a non-display area in which pixels PX are not arranged. A driver or the like for providing electrical signals or power to the pixels PX may be arranged in the peripheral area PA. Pads to which various electronic devices, printed circuit boards, or the like may be electrically connected may be arranged in the peripheral area PA. The pads may be arranged apart from each other in the peripheral area PA and may each be electrically connected to a printed circuit board or an integrated circuit device.

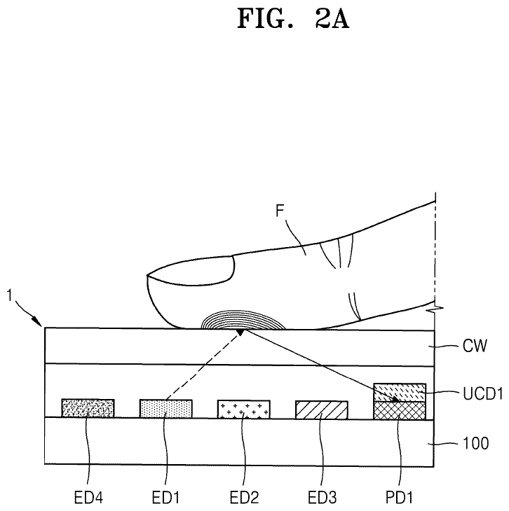

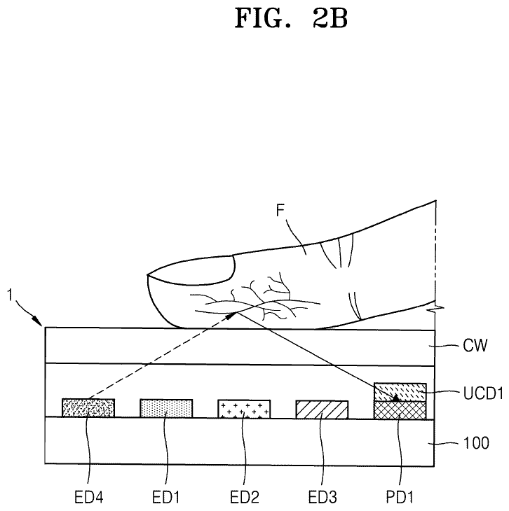

FIGS. 2A and 2B are each a schematic cross-sectional view of the display apparatus 1 according to an embodiment of the present invention.

Referring to FIGS. 2A and 2B, the display apparatus 1 according to an embodiment of the present invention may further include an optical sensor, in addition to the plurality of pixels PX (see FIG. 1). Each of the plurality of pixels PX (see FIG. 1) may include at least one of a first light-emitting device ED1, a second light-emitting device ED2, or a third light-emitting device ED3, and the optical sensor may include a first light-receiving device PD1. The first light-emitting device ED1, the second light-emitting device ED2, and the third light-emitting device ED3 may emit light of different colors from each other. For example, the first light-emitting device ED1 may emit green light. Further, the second light-emitting device ED2 may emit blue light, and the third light-emitting device ED3 may emit red light.

In embodiments of the present invention, the display apparatus 1 may further include an auxiliary light-emitting device ED4, in addition to the first to third light-emitting devices ED1, ED2, and ED3. An emission layer of the auxiliary light-emitting device ED4 may emit light having a longer wavelength than that of the light that is emitted from each of the first light-emitting device ED1, the second light-emitting device ED2, and the third light-emitting device ED3. For example, the emission layer of the auxiliary light-emitting device ED4 may emit light in the near-infrared wavelength band. As shown in FIGS. 2A and 2B, the auxiliary light-emitting device ED4 may be arranged on the same layer as the first light-emitting device ED1, the second light-emitting device ED2, and the third light-emitting device ED3, but embodiments are not limited thereto. In an embodiment of the present invention, the auxiliary light-emitting device ED4 may be arranged outside the display apparatus 1, for example, below the substrate 100. In addition, in an embodiment of the present invention, the auxiliary light-emitting device ED4 may be omitted.

A first upconversion device UCD1 may be disposed on the first light-receiving device PD1. The first upconversion device UCD1 may convert light having low energy into light having high energy. For example, the first upconversion device UCD1 may convert light having a long wavelength into light having a short wavelength. For example, the first upconversion device UCD1 may convert light in the near-infrared wavelength band into light in the visible light wavelength band and emit the converted light. However, embodiments of the present invention are not limited thereto, and the first upconversion device UCD1 may convert light having a long wavelength into light having a short wavelength even within the visible light wavelength band. For example, the first upconversion device UCD1 may convert red light into green light.

As shown in FIG. 2A, the display apparatus 1 may have a function of sensing an object that is in contact with a cover window CW, for example, a fingerprint of a finger F. Among light emitted from at least one of the first light-emitting device ED1, the second light-emitting device ED2, or the third light-emitting device ED3, at least a portion of the emitted light may be reflected by a user's fingerprint, and at least a portion of the reflected light that is reflected by the user's fingerprint may be re-incident on the first light-receiving device PD1, and thus, the first light-receiving device PD1 may detect the reflected light. For example, green light emitted from the first light-emitting device ED1 may be reflected by an object that is in contact with the cover window CW and be re-incident on the first light-receiving device PD1, and thus, the first light-receiving device PD1 may detect the re-incident green light.

In addition, as shown in FIG. 2B, the display apparatus 1 may have a function of sensing biometric information or touch information of an object that is in contact with the cover window CW, for example, the finger F. For example, light in the near-infrared wavelength band emitted from the auxiliary light-emitting device ED4 may be reflected by an object and then re-incident on the first upconversion device UCD1. The light in the near-infrared wavelength band input to the first upconversion device UCD1 may be converted into light in the visible light wavelength band and then emitted. Thereafter, the light in the visible light wavelength band that is emitted from the first upconversion device UCD1 may be incident on the first light-receiving device PD1, and thus, the first light-receiving device PD1 may detect the light in the near-infrared wavelength band that is reflected by the object.

Light in the near-infrared wavelength band has a longer wavelength and thus may penetrate deeper into an object than light in the visible light wavelength band, thereby securing more diverse sensing information, such as biometric information. For example, when hemoglobin combines with or dissociates from oxygen in blood vessels of an object, the absorption rate of light in the near-infrared wavelength band (or, for example, red light) may vary, and thus, oxygen saturation may be measured through detection of the light in the near-infrared wavelength band (or, for example, the red light). In conclusion, the optical sensor including the first light-receiving device PD1 on which the first upconversion device UCD1 is disposed may sense biometric information or touch information including a user's oxygen saturation, pulse, and blood pressure.

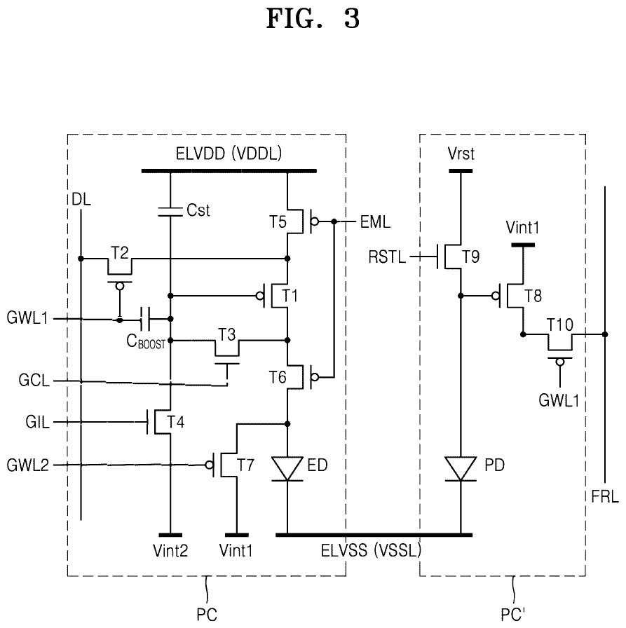

FIG. 3 is a circuit diagram of a pixel circuit PC, which is electrically connected to a light-emitting device ED of the display apparatus 1, and a sensor circuit PC′, which is electrically connected to a light-receiving device PD of the display apparatus 1, according to an embodiment of the present invention.

Referring to FIG. 3, the pixel PX (see FIG. 1) may include the light-emitting device ED and the pixel circuit PC that controls the amount of light that is emitted from the light-emitting device ED, and the optical sensor may include the light-receiving device PD and the sensor circuit PC′ that controls the amount of light that is received by the light-receiving device PD.

Each pixel circuit PC may be connected to a scan start line GIL, a scan control line GCL, a first scan write line GWL1, a second scan write line GWL2, an emission line EML, and a data line DL. In addition, each pixel circuit PC may be connected to a first driving voltage line VDDL to which a first driving voltage ELVDD is applied, a second driving voltage line VSSL to which a second driving voltage ELVSS is applied, a first initialization voltage line to which a first initialization voltage Vint1 is applied, and a second initialization voltage line to which a second initialization voltage Vint2 is applied.

Each sensor circuit PC′ may be connected to the first scan write line GWL1, a reset line RSTL, and a fingerprint detection line FRL. In addition, each sensor circuit PC′ may be connected to the second driving voltage line VSSL to which the second driving voltage ELVSS is applied, a reset voltage line to which a reset voltage Vrst is applied, and the first initialization voltage line to which the first initialization voltage Vint1 is applied.

Each pixel circuit PC may include a plurality of transistors and at least one capacitor and may be connected to the light-emitting device ED. The plurality of transistors may include first to seventh transistors T1, T2, T3, T4, T5, T6, and T7. Among the plurality of transistors, the first transistor T1 may be a driving transistor, and the second to seventh transistors T2 to T7 may be transistors that act as switch devices, which are turned on or turned off according to scan signals that are applied to respective gate electrodes of the transistors T2 to T7.

The first transistor T1 may include a gate electrode, a first electrode, and a second electrode. The gate electrode of the first transistor T1 may be connected to a first electrode of the third transistor T3 and one electrode of a storage capacitor Cst. The first electrode of the first transistor T1 may be connected to a second electrode of the second transistor T2 and a second electrode of the fifth transistor T5, and the second electrode of the first transistor T1 may be connected to a second electrode of the third transistor T3 and a first electrode of the sixth transistor T6.

The light-emitting device ED may emit light according to a driving current. The amount of light emitted from the light-emitting device ED may be proportional to the driving current. The light-emitting device ED may be an organic light-emitting diode including a pixel electrode, a counter electrode, and an organic emission layer that is arranged between the pixel electrode and the counter electrode. In addition, the light-emitting device ED may be an inorganic light-emitting diode including an inorganic emission layer arranged between a pixel electrode and a counter electrode, or may be a quantum dot light-emitting diode including a quantum dot emission layer arranged between a pixel electrode and a counter electrode. In addition, the light-emitting device ED may be a micro-light-emitting diode. The pixel electrode of the light-emitting device ED may be connected to a second electrode of the sixth transistor T6 and a second electrode of the seventh transistor T7, and the counter electrode of the light-emitting device ED may be connected to the second driving voltage line VSSL.

The second transistor T2 may be turned on by a scan signal of the first scan write line GWL1 to connect the first electrode of the first transistor T1 and the data line DL to each other. A gate electrode of the second transistor T2 may be connected to the first scan write line GWL1. A first electrode of the second transistor T2 may be connected to the data line DL, and the second electrode of the second transistor T2 may be connected to the first electrode of the first transistor T1.

The third transistor T3 may be turned on by a scan signal of the scan control line GCL to connect the gate electrode and the second electrode of the first transistor T1 to each other. For example, when the third transistor T3 is turned on, the gate electrode and the second electrode of the first transistor T1 may be connected to each other, and thus, the first transistor T1 may be driven as a diode. A gate electrode of the third transistor T3 may be connected to the scan control line GCL. The first electrode of the third transistor T3 may be connected to the second electrode of the first transistor T1, and the second electrode of the third transistor T3 may be connected to the gate electrode of the first transistor T1.

The fourth transistor T4 may be turned on by a scan signal of the scan start line GIL to connect the gate electrode of the first transistor T1 and the second initialization voltage line to each other. In this case, the gate electrode of the first transistor T1 may be discharged to the second initialization voltage Vint2 of the second initialization voltage line. A gate electrode of the fourth transistor T4 may be connected to the scan start line GIL. The first electrode of the fourth transistor T4 may be connected to the second initialization voltage line, and a second electrode of the fourth transistor T4 may be connected to the gate electrode of the first transistor T1.

The fifth transistor T5 may be turned on by an emission signal of the emission line EML to connect the first electrode of the first transistor T1 and the first driving voltage line VDDL to each other. A gate electrode of the fifth transistor T5 may be connected to the emission line EML. A first electrode of the fifth transistor T5 may be connected to the first driving voltage line VDDL, and the second electrode of the fifth transistor T5 may be connected to the first electrode of the first transistor T1.

The sixth transistor T6 may be turned on by an emission signal of the emission line EML to connect the second electrode of the first transistor T1 and the pixel electrode of the light-emitting device ED to each other. A gate electrode of the sixth transistor T6 may be connected to the emission line EML. The first electrode of the sixth transistor T6 may be connected to the second electrode of the first transistor T1, and the second electrode of the sixth transistor T6 may be connected to the pixel electrode of the light-emitting device ED. When both the fifth transistor T5 and the sixth transistor T6 are turned on, a driving current may be supplied to the light-emitting device ED.

The seventh transistor T7 may be turned on by a scan signal of the second scan write line GWL2 to connect the first initialization voltage line and the pixel electrode of the light-emitting device ED to each other. In this case, the pixel electrode of the light-emitting device ED may be discharged to the first initialization voltage Vint1. A gate electrode of the seventh transistor T7 may be connected to the second scan write line GWL2. A first electrode of the seventh transistor T7 may be connected to the first initialization voltage line, and the second electrode of the seventh transistor T7 may be connected to the pixel electrode of the light-emitting device ED.

The storage capacitor Cst may be formed between the gate electrode of the first transistor T1 and the first driving voltage line VDDL. One electrode of the storage capacitor Cst may be connected to the gate electrode of the first transistor T1, and the other electrode of the storage capacitor Cst may be connected to the first driving voltage line VDDL. As a result, the storage capacitor Cst may maintain an electric potential difference between the gate electrode of the first transistor T1 and the first driving voltage line VDDL.

A boost capacitor CBOOST may be formed between the gate electrode of the second transistor T2 and the gate electrode of the first transistor T1. One electrode of the boost capacitor CBOOST may be connected to the first scan write line GWL1, which is connected to the gate electrode of the second transistor T2, and the other electrode of the boost capacitor CBOOST may be connected to the gate electrode of the first transistor T1 and one electrode of the storage capacitor Cst. The boost capacitor CBOOST may be a boosting capacitor, and when a signal of the first scan write line GWL1 is a voltage that turns off the second transistor T2, boost capacitor CBOOST may increase a voltage of a node to reduce a voltage displaying black (a black voltage).

Each sensor circuit PC′ may include a plurality of transistors and may be connected to the light-receiving device PD. The plurality of transistors may include eighth to tenth transistors T8, T9, and T10. Among the plurality of transistors, the eighth transistor T8 may be a driving transistor, and the ninth transistor T9 and the tenth transistor T10 may be transistors serving as switch devices, which are turned on or turned off according to scan signals applied to respective gate electrodes of the transistors.

When a plurality of light-emitting devices ED and a plurality of light-receiving devices PD are arranged in one display apparatus 1 (see FIG. 1), a voltage wire or a signal wire for driving the light-emitting device ED may be commonly used in driving the light-receiving device PD. For example, by reducing the additional arrangement of voltage wires or signal wires for driving the plurality of light-receiving devices PD in the display apparatus 1 (see FIG. 1), the resolution of the display apparatus 1 (see FIG. 1) may be secured, and the peripheral area PA (see FIG. 1) may be reduced. For example, a signal wire connected to the gate electrode of the second transistor T2 of the pixel PX (see FIG. 1) may be commonly used with a signal wire that is connected to a gate electrode of the tenth transistor T10 of the optical sensor. For example, the gate electrode of the second transistor T2 and the gate electrode of the tenth transistor T10 may be connected to the first scan write line GWL1. As another example, the second driving voltage line VSSL may be a common voltage wire that is connected to the counter electrode of the light-emitting device ED and a counter electrode of the light-receiving device PD. As another example, the first initialization voltage line that applies the first initialization voltage Vint1 may be a common voltage wire that is connected to a second electrode of the eighth transistor T8 of the optical sensor and the second electrode of the seventh transistor T7.

Each light-receiving device PD may be a light-receiving diode including a sensing electrode, a counter electrode, and a photoelectric conversion layer that is arranged between the sensing electrode and the counter electrode. Each light-receiving device PD may convert light incident from the outside into an electrical signal. The light-receiving device PD may be a light-receiving diode or a phototransistor including a pn-type or pin-type inorganic material. In addition, the light-receiving device PD may be an organic light-receiving diode including an electron-donating material that generates donor ions and an electron-accepting material that generates acceptor ions.

When the light-receiving device PD is exposed to external light, photocharges may be generated, and the generated photocharges may be accumulated in the sensing electrode of the light-receiving device PD. In this case, a voltage of a node that is electrically connected to the sensing electrode may increase. When the light-receiving device PD and the fingerprint detection line FRL are connected to each other according to the turn-on of the eighth transistor T8 and the tenth transistor T10, a current may flow in the fingerprint detection line FRL in proportion to a voltage of a node in which charges are accumulated.

The eighth transistor T8 may be turned on by a voltage that is applied to a gate electrode of the eighth transistor T8 to connect the first initialization voltage line and a first electrode of the tenth transistor T10 to each other. In this case, a second electrode of the tenth transistor T10 may be discharged to the first initialization voltage Vint1. The gate electrode of the eighth transistor T8 may be connected to a node that is between the ninth transistor T9 and the light-receiving device PD. A first electrode of the eighth transistor T8 may be connected to the first initialization voltage line, and the second electrode of the eighth transistor T8 may be connected to the first electrode of the tenth transistor T10. The eighth transistor T8 may be a source follower amplifier that generates a source-drain current in proportion to the amount of charge of a node input to the gate electrode of the eighth transistor T8. The first electrode of the eighth transistor T8 may be connected to the first driving voltage line VDDL or the second initialization voltage line.

The tenth transistor T10 may be turned on by a scan signal of the first scan write line GWL1 to connect the second electrode of the eighth transistor T8 and the fingerprint detection line FRL to each other. The fingerprint detection line FRL may be configured to transmit a fingerprint detection signal to a read-out circuit. The gate electrode of the tenth transistor T10 may be connected to the first scan write line GWL1. The first electrode of the tenth transistor T10 may be connected to the second electrode of the eighth transistor T8, and the second electrode of the tenth transistor T10 may be connected to the fingerprint detection line FRL.

The ninth transistor T9 may be turned on by a reset signal of the reset line RSTL to reset a node that is connected to the gate electrode of the eighth transistor T8 to the reset voltage Vrst. A gate electrode of the ninth transistor T9 may be connected to the reset line RSTL. A first electrode of the ninth transistor T9 may be connected to the reset voltage line, and a second electrode of the ninth transistor T9 may be connected to a node that connects the light-receiving device PD and the eighth transistor T8 to each other. When a reset driver that outputs a reset signal of the reset line RSTL is omitted, the ninth transistor T9 may be turned on by a scan signal.

When the first electrode of each of the first to tenth transistors T1, T2, T3, T4, T5, T6, T7, T8, T9, and T10 is a source electrode, the second electrode of each of the first to tenth transistors T1, T2, T3, T4, T5, T6, T7, T8, T9, and T10 may be a drain electrode. In addition, when the first electrode of each of the first to tenth transistors T1, T2, T3, T4, T5, T6, T7, T8, T9, and T10 is a drain electrode, the second electrode of each of the first to tenth transistors T1, T2, T3, T4, T5, T6, T7, T8, T9, and T10 may be a source electrode.

An active layer of each of the first to tenth transistors T1, T2, T3, T4, T5, T6, T7, T8, T9, and T10 may include any one of polysilicon, amorphous silicon, and/or an oxide semiconductor. For example, the first and second transistors T1 and T2, the fifth to eighth transistors T5, T6, T7, and T8, and the tenth transistor T10 may be P-type transistors. In this case, the active layer of each of the first and second transistors T1 and T2, the fifth to eighth transistors T5, T6, T7, and T8, and the tenth transistor T10 may include polysilicon. In addition, each of the third transistor T3, the fourth transistor T4, and the ninth transistor T9 may be an N-type transistor that includes an active layer of an oxide semiconductor.

However, embodiments of the present invention are not limited thereto, and each of the first to tenth transistors T1, T2, T3, T4, T5, T6, T7, T8, T9, and T10 may be a P-type transistor. As an example, the eighth to tenth transistors T8, T9, and T10 may be formed as P-type transistors.

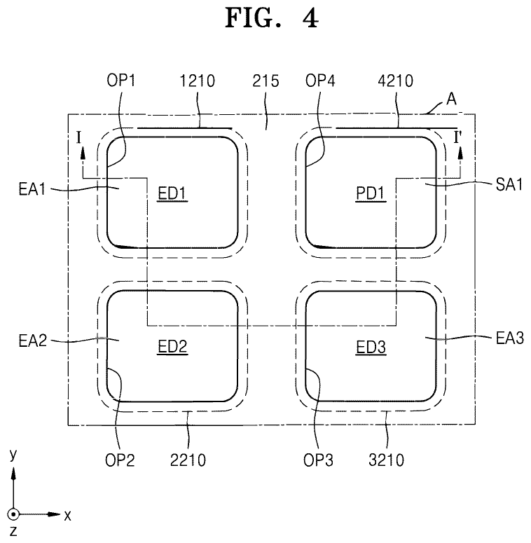

FIG. 4 is a schematic plan view of a portion of the display apparatus 1 according to an embodiment of the present invention. In detail, FIG. 4 is a schematic enlarged plan view of region A of FIG. 1. In FIG. 4, a plan view over a bank layer 215 is illustrated for convenience.

Referring to FIG. 4, the display apparatus 1 may include a plurality of light-emitting devices and a plurality of light-receiving devices. The plurality of light-emitting devices may include the first light-emitting device ED1, the second light-emitting device ED2, and the third light-emitting device ED3, and the plurality of light-receiving devices may include the first light-receiving device PD1. The first light-emitting device ED1, the second light-emitting device ED2, and the third light-emitting device ED3 may emit light of different colors from each other. For example, the first light-emitting device ED1 may emit green light. The second light-emitting device ED2 may emit red light, and the third light-emitting device ED3 may emit blue light. The red light may be light in a wavelength band of about 580 nm to about 780 nm. The blue light may be light in a wavelength band of about 380 nm to about 495 nm, and the green light may be light in a wavelength band of about 495 nm to about 580 nm. The first light-receiving device PD1 may detect light that is emitted from the first light-emitting device ED1, the second light-emitting device ED2, and/or the third light-emitting device ED3 and that is reflected by an object. Further, the light receiving device PD1 may sense the object.

Each light-emitting device may include a pixel electrode, a counter electrode, and an intermediate layer arranged therebetween, and each light-receiving device may include a sensing electrode, a counter electrode, and an intermediate layer arranged therebetween. Accordingly, the first light-emitting device ED1 may include a first pixel electrode 1210. The second light-emitting device ED2 may include a second pixel electrode 2210, and the third light-emitting device ED3 may include a third pixel electrode 3210. The first light-receiving device PD1 may include a first sensing electrode 4210. The first pixel electrode 1210, the second pixel electrode 2210, the third pixel electrode 3210, and the first sensing electrode 4210 may be arranged apart from each other on the substrate 100 (see to FIG. 5). As used herein, the expression “in a plan view” refers to a plan view taken in a direction perpendicular to the substrate 100. That is, the expression “A and B apart from each other in a plan view” refers to “A and B apart from each other when viewed in a direction perpendicular to the substrate 100.”

The bank layer 215 may be disposed on the first pixel electrode 1210, the second pixel electrode 2210, the third pixel electrode 3210, and the first sensing electrode 4210 and may cover an edge of each of the first pixel electrode 1210, the second pixel electrode 2210, the third pixel electrode 3210, and the first sensing electrode 4210. For example, the bank layer 215 may have a first opening OP1 exposing a central portion of the first pixel electrode 1210, a second opening OP2 exposing a central portion of the second pixel electrode 2210, a third opening OP3 exposing a central portion of the third pixel electrode 3210, and a fourth opening OP4 exposing a central portion of the first sensing electrode 4210.

Although not shown in FIG. 4, emission layers for emitting light may be respectively arranged in the first opening OP1, the second opening OP2, and the third opening OP3 of the bank layer 215, and active layers for detecting light may each be arranged in the fourth opening OP4 of the bank layer 215. A counter electrode may be disposed on the emission layers and active layers. As described above, a stacked structure of a pixel electrode, an emission layer, and a counter electrode may constitute one light-emitting device. In addition, as described above, a stacked structure of a sensing electrode, an active layer, and a counter electrode may constitute one light-receiving device. One opening of the bank layer 215 may correspond to one light-emitting device and may define one emission area. In addition, one opening of the bank layer 215 may correspond to one light-receiving device and may define one sensing area.

For example, an emission layer for emitting green light may be arranged in the first opening OP1, and thus, the first opening OP1 may provide a first emission area EA1. Similarly, an emission layer for emitting red light may be arranged in the second opening OP2, and thus, the second opening OP2 may provide a second emission area EA2. An emission layer for emitting blue light may be arranged in the third opening OP3, and thus, the third opening OP3 may provide a third emission area EA3. An active layer for detecting light may be arranged in the fourth opening OP4, and thus, the fourth opening OP4 may provide a first sensing area SA1.

Accordingly, the area size of the first opening OP1 may be the same as the area size of the first emission area EA1. The area size of the second opening OP2 may be the same as the area size of the second emission area EA2, and the area size of the third opening OP3 may be the same as the area size of the third emission area EA3. The area size of the fourth opening OP4 may be the same the area size of the first sensing area SA1.

Each of the first opening OP1, the second opening OP2, the third opening OP3, and the fourth opening OP4 may have a polygonal shape when viewed in a direction (a z-axis direction) perpendicular to the substrate 100 (see to FIG. 5). In other words, each of the first emission area EA1, the second emission area EA2, the third emission area EA3, and the first sensing area SA1 may have a polygonal shape when viewed in the direction (the z-axis direction) perpendicular to the substrate 100. FIG. 4 shows that each of the first emission area EA1, the second emission area EA2, the third emission area EA3, and the first sensing area SA1 has a quadrangular shape, for example, a quadrangular shape with round corners, when viewed in the direction (the z-axis direction) perpendicular to the substrate 100. However, embodiments of the present invention are not limited thereto. For example, each of the first emission area EA1, the second emission area EA2, the third emission area EA3, and the first sensing area SA1 may have a circular shape or an oval shape when viewed in the direction (the z-axis direction) perpendicular to the substrate 100.

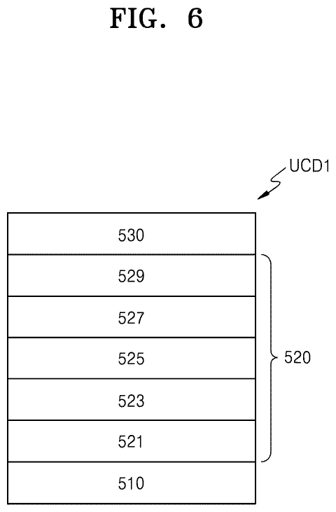

FIG. 5 is a schematic cross-sectional view of a portion of the display apparatus 1 according to an embodiment of the present invention. In detail, FIG. 5 is a schematic cross-sectional view of a cross-section of the display apparatus 1 of FIG. 4, taken along line I-I′. FIG. 6 is a schematic conceptual diagram of a portion of the display apparatus 1 according to an embodiment of the present invention. In detail, FIG. 6 is a schematic cross-sectional view of a stacked structure of the first upconversion device UCD1 of the display apparatus 1 according to an embodiment of the present invention.

As shown in FIG. 5, the display apparatus 1 according to the present embodiment may include the substrate 100. The substrate 100 may include various materials having flexible or bendable characteristics. For example, the substrate 100 may include glass, metal, or polymer resin. In addition, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications are possible, for example, the substrate 100 may have a multi-layer structure including two layers and a barrier layer arranged between the two layers and including an inorganic material, such as silicon oxide, silicon nitride, or silicon oxynitride. Each layer of the two layers may include, for example, a polymer resin.

The first to third light-emitting devices ED1, ED2, and ED3, the first light-receiving device PD1, the pixel circuit PC, and the sensor circuit PC′ may be disposed on the substrate 100. The pixel circuit PC may be electrically connected to each of the first to third light-emitting devices ED1, ED2, and ED3, and the sensor circuit PC′ may be electrically connected to the first light-receiving device PD1.

Because the first light-emitting device ED1, the second light-emitting device ED2, and the third light-emitting device ED3 are electrically connected to the pixel circuit PC, light emission may be controlled. In addition, because the first light-receiving device PD1 is electrically connected to the sensor circuit PC′, light detection may be controlled. The pixel circuit PC may include a plurality of thin-film transistors TFT and the storage capacitor Cst and may have substantially the same structure as the pixel circuit PC described with reference to FIG. 3. In FIG. 5, one thin-film transistor TFT is shown for convenience of illustration, and the thin-film transistor TFT may correspond to the first transistor T1 (see FIG. 3) described above. Likewise, the sensor circuit PC′ may include a plurality of thin-film transistors TFT′ and may have substantially the same structure as the sensor circuit PC′ described with reference to FIG. 3. In FIG. 5, one thin-film transistor TFT′ is shown for convenience of illustration, and the thin-film transistor TFT′ may correspond to the eighth transistor T8 (see FIG. 3) described above. Hereinafter, for convenience of description, one pixel circuit PC is mainly described.

A buffer layer 201 including an inorganic material, such as silicon oxide, silicon nitride, and/or silicon oxynitride, may be arranged between the thin-film transistor TFT and the substrate 100. The buffer layer 201 may increase the smoothness of an upper surface of the substrate 100 or may prevent or reduce penetration of impurities from the substrate 100 to a semiconductor layer Act of the thin-film transistor TFT.

As shown in FIG. 5, the thin-film transistor TFT may include the semiconductor layer Act including, for example, amorphous silicon, polysilicon, an organic semiconductor material, or an oxide semiconductor material. In addition, the thin-film transistor TFT may include a gate electrode GE, a source electrode SE, and/or a drain electrode DE. The gate electrode GE may include various conductive materials and may have various layered structures. For example, the gate electrode GE may include a Mo layer and an Al layer. In addition, the gate electrode GE may include, for example, a TiNX layer, an Al layer, and/or a Ti layer. Each of the source electrode SE and the drain electrode DE may also include various conductive materials and may have various layered structures. For example, each of the source electrode SE and the drain electrode DE may include a Ti layer, an Al layer, and/or a Cu layer.

To ensure insulation between the semiconductor layer Act and the gate electrode GE, a gate insulating layer 203 including an inorganic material, such as silicon oxide, silicon nitride, and/or silicon oxynitride, may be arranged between the semiconductor layer Act and the gate electrode GE. FIG. 5 shows that the gate insulating layer 203 has a shape corresponding to the entire surface of the substrate 100 and has a structure in which contact holes are formed in predetermined portions, but embodiments of the present invention are not limited thereto. For example, the gate insulating layer 203 may be patterned to have the same shape as the gate electrode GE.

In addition, a first interlayer insulating layer 205 including an inorganic material, such as silicon oxide, silicon nitride, and/or silicon oxynitride, may be disposed on the gate electrode GE. The first interlayer insulating layer 205 may have a single-layer or multi-layer structure including the material described above. The first interlayer insulating layer 205 may be formed through chemical vapor deposition (CVD) or atomic layer deposition (ALD).

The storage capacitor Cst may include a first electrode CE1 and a second electrode CE2, which overlap each other with the first interlayer insulating layer 205 disposed therebetween. The storage capacitor Cst may overlap the thin-film transistor TFT. In this regard, FIG. 5 shows that the gate electrode GE of the thin-film transistor TFT is the first electrode CE1 of the storage capacitor Cst, but embodiments of the present invention are not limited thereto. For example, the storage capacitor Cst might not overlap the thin-film transistor TFT. The second electrode CE2 of the storage capacitor Cst may include, for example, a conductive material including Mo, Al, Cu, and Ti, and may have a single-layer or multi-layer structure including the above material.

A second interlayer insulating layer 207 including an inorganic material, such as silicon oxide, silicon nitride, and/or silicon oxynitride, may be disposed on the second electrode CE2 of the storage capacitor Cst. The second interlayer insulating layer 207 may have a single-layer or multi-layer structure including the material described above.

The source electrode SE and the drain electrode DE may be disposed on the second interlayer insulating layer 207. Each of the source electrode SE and the drain electrode DE may include a material having excellent conductivity. Each of the source electrode SE and the drain electrode DE may include a conductive material including, for example, Mo, Al, Cu, and Ti may have a single-layer or multi-layer structure including the above material. For example, each of the source electrode SE and the drain electrode DE may have a multi-layer structure of Ti/Al/Ti. However, embodiments of the present invention are not limited thereto. For example, the thin-film transistor TFT may include only one of the source electrode SE or the drain electrode DE, or might not include both the source electrode SE and the drain electrode DE.

A planarization layer 208 may be arranged to cover the thin-film transistor TFT and the storage capacitor Cst. The planarization layer 208 may include an organic insulating material. For example, the planarization layer 208 may include benzocyclobutene (BCB), polyimide, hexamethyldisiloxane (HMDSO), polymethylmethacrylate (PMMA), polystyrene, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or a mixture thereof. A third interlayer insulating layer may be disposed below the planarization layer 208. The third interlayer insulating layer may include an inorganic insulating material, such as silicon oxide, silicon nitride, or silicon oxynitride.

The first light-emitting device ED1, the second light-emitting device ED2, the third light-emitting device ED3, and the first light-receiving device PD1 may be arranged apart from each other on the planarization layer 208. The first light-emitting device ED1, the second light-emitting device ED2, and the third light-emitting device ED3 may emit light of different colors from each other. For example, the first light-emitting device ED1 may emit green light. The second light-emitting device ED2 may emit red light, and the third light-emitting device ED3 may emit blue light. The first light-receiving device PD1 may detect light that is emitted from the first to third light-emitting devices ED1, ED2, and ED3 and reflected by an object. In addition, the auxiliary light-emitting device ED4 (see FIG. 2A) may be disposed on the planarization layer 208. Light that is emitted from the auxiliary light-emitting device ED4 (see FIG. 2A) and reflected by an object may be converted through the first upconversion device UCD1 and then incident on the first light-receiving device PD1.

The first light-emitting device ED1 may include the first pixel electrode 1210, a first intermediate layer 1220, and a counter electrode 230. The second light-emitting device ED2 may include the second pixel electrode 2210, a second intermediate layer 2220, and the counter electrode 230. The third light-emitting device ED3 may include the third pixel electrode 3210, a third intermediate layer 3220, and the counter electrode 230. The first light-receiving device PD1 may include the first sensing electrode 4210, a fourth intermediate layer 4220, and the counter electrode 230. For example, the first pixel electrode 1210, the second pixel electrode 2210, the third pixel electrode 3210, and the first sensing electrode 4210 respectively included in the first light-emitting device ED1, the second light-emitting device ED2, the third light-emitting device ED3, and the first light-receiving device PD1 may be patterned and provided for each pixel. The counter electrode 230 of the first light-emitting device ED1, the second light-emitting device ED2, the third light-emitting device ED3, and the first light-receiving device PD1 may be provided as a single body across the first light-emitting device ED1, the second light-emitting device ED2, the third light-emitting device ED3, and the first light-receiving device PD1. Each of the first intermediate layer 1220, the second intermediate layer 2220, the third intermediate layer 3220, and the fourth intermediate layer 4220 may be arranged between the counter electrode 230 and each of the first pixel electrode 1210, the second pixel electrode 2210, the third pixel electrode 3210, and the first sensing electrode 4210, respectively.

The first pixel electrode 1210, the second pixel electrode 2210, the third pixel electrode 3210, and the first sensing electrode 4210 may be arranged apart from each other on the substrate 100. The first pixel electrode 1210, the second pixel electrode 2210, the third pixel electrode 3210, and the first sensing electrode 4210 may be reflective electrodes. For example, each of the first pixel electrode 1210, the second pixel electrode 2210, the third pixel electrode 3210, and the first sensing electrode 4210 may include a light-transmissive conductive layer including a light-transmissive conductive oxide, such as ITO, In₂O₃, or IZO, and a reflective layer including a metal, such as Al or Ag. For example, each of the first pixel electrode 1210, the second pixel electrode 2210, the third pixel electrode 3210, and the first sensing electrode 4210 may have a three-layer structure of ITO/Ag/ITO.

As shown in FIG. 5, each of the first pixel electrode 1210, the second pixel electrode 2210, and the third pixel electrode 3210 may be electrically connected to the thin-film transistor TFT by contacting any one of the source electrode SE or the drain electrode DE. For example, each of the first pixel electrode 1210, the second pixel electrode 2210, and the third pixel electrode 3210 may contact any one of the source electrode SE and the drain electrode DE through a contact hole that is formed in the planarization layer 208. Likewise, the first sensing electrode 4210 may be electrically connected to the thin-film transistor TFT′ through a contact hole that is formed in the planarization layer 208.

The bank layer 215 may be disposed on the planarization layer 208. The bank layer 215 may have an opening corresponding to each of the first to third light-emitting devices ED1, ED2, and ED3 and the first light-receiving device PD1, that is, an opening exposing at least a central portion of a pixel electrode (or a sensing electrode), thereby providing an emission area and a sensing area. For example, the bank layer 215 may have a plurality of openings, for example, the first to fourth openings OP1, OP2, OP3, and OP4, exposing respective central portions of the first pixel electrode 1210, the second pixel electrode 2210, the third pixel electrode 3210, and the first sensing electrode 4210. In addition, the bank layer 215 may increase a distance between a pixel electrode 210 and the counter electrode 230 or a distance between the first sensing electrode 4210 and the counter electrode 230. As a result, an arc or the like may be prevented from occurring at an edge of the pixel electrode 210 or an edge of the first sensing electrode 4210. The bank layer 215 may include an organic material, such as polyimide or HMDSO.

The counter electrode 230 may be disposed on the first pixel electrode 1210. The counter electrode 230 may be provided as a single body across the first light-emitting device ED1, the second light-emitting device ED2, the third light-emitting device ED3, and the first light-receiving device PD1. Accordingly, the counter electrode 230 may also be disposed on the second pixel electrode 2210, the third pixel electrode 3210, and the first sensing electrode 4210. The counter electrode 230 may be a semi-transmissive electrode or a transmissive electrode. For example, the counter electrode 230 may be a transmissive electrode including a transmissive conductive layer including ITO, In₂O₃, or IZO, or may be a semi-transmissive electrode including a semi-transmissive layer including a metal, such as Al or Ag. For example, the counter electrode 230 may be a semi-transmissive layer including at least one of Mg and Ag.

An intermediate layer may be arranged between the pixel electrode 210 and the counter electrode 230 and between the first sensing electrode 4210 and the counter electrode 230. The intermediate layer may include the first intermediate layer 1220, the second intermediate layer 2220, the third intermediate layer 3220, and the fourth intermediate layer 4220. The first intermediate layer 1220 may be arranged between the first pixel electrode 1210 and the counter electrode 230. The second intermediate layer 2220 may be arranged between the second pixel electrode 2210 and the counter electrode 230, and the third intermediate layer 3220 may be arranged between the third pixel electrode 3210 and the counter electrode 230. The fourth intermediate layer 4220 may be arranged between the first sensing electrode 4210 and the counter electrode 230.

The first intermediate layer 1220 may include a first common layer 221, a second common layer 222, a first emission layer 1223, a buffer layer, a third common layer 225, and a fourth common layer 226. The second intermediate layer 2220 may include the first common layer 221, the second common layer 222, a second emission layer 2223, the buffer layer, the third common layer 225, and the fourth common layer 226. The third intermediate layer 3220 may include the first common layer 221, the second common layer 222, a third emission layer 3223, the buffer layer, the third common layer 225, and the fourth common layer 226. The fourth intermediate layer 4220 may include the first common layer 221, the second common layer 222, a first active layer 4223, the buffer layer, the third common layer 225, and the fourth common layer 226.

In this case, each of the first common layer 221, the second common layer 222, the buffer layer, the third common layer 225, and the fourth common layer 226 may be provided as a single body across the first to third light-emitting devices ED1, ED2, and ED3 and the first light-receiving device PD1. For example, the first common layer 221, the second common layer 222, the buffer layer (not shown), the third common layer 225, and the fourth common layer 226 may be formed over the entire surface of the substrate 100. An emission layer 223 and the first active layer 4223 may be individually patterned and provided for each light-emitting device and each light-receiving device.

As described above, the first light-emitting device ED1 may emit green light. The second light-emitting device ED2 may emit red light, and the third light-emitting device ED3 may emit blue light. To implement such light emission, the first emission layer 1223 may emit green light. The second emission layer 2223 may emit red light, and the third emission layer 3223 may emit blue light. The first light-receiving device PD1 may detect light that is emitted from the first to third light-emitting devices ED1, ED2, and ED3 and reflected by an object. To implement such light detection, the first active layer 4223 may absorb light in the visible light band. For example, the first active layer 4223 may absorb green light.

The emission layer 223 may include an organic material including a fluorescent or phosphorescent material that emits red, green, blue, or white light. The emission layer 223 may be an organic emission layer including a low-molecular weight organic material or a polymer organic material. For example, the emission layer 223 may be an organic emission layer and may include copper phthalocyanine, tris-8-hydroxyquinoline aluminum, a poly-phenylenevinylene (PPV)-based material, or a polyfluorene-based material.

In an embodiment of the present invention, the emission layer 223 may include a host material and a dopant material. The dopant material may be a material that emits light of a certain color and may include a light-emitting material. The light-emitting material may include at least one of, for example, a phosphorescent dopant, a fluorescent dopant, and a quantum dot. The host material may be a main material of the emission layer 223 and may be a material that helps the dopant material to emit light.

The first active layer 4223 may receive light from the outside to generate excitons and then may separate the generated excitons into holes and electrons. When a (+) electric potential is applied to the first sensing electrode 4210 and a (−) electric potential is applied to the counter electrode 230, holes that are separated in the first active layer 4223 may move toward the counter electrode 230, and electrons that are separated in the first active layer 4223 may move toward the first sensing electrode 4210. Accordingly, a photocurrent may be formed in a direction from the first sensing electrode 4210 to the counter electrode 230. When a bias is applied between the first sensing electrode 4210 and the counter electrode 230, a dark current may flow through the first light-receiving device PD1. The first light-receiving device PD1 may detect the amount of light based on the ratio of the photocurrent to the dark current.

The first active layer 4223 may include a p-type semiconductor compound and an n-type semiconductor compound. For example, the first active layer 4223 may be a mixed layer including a p-type semiconductor compound and an n-type semiconductor compound. In addition, the first active layer 4223 may have a structure in which a layer including a p-type semiconductor compound and a layer including an n-type semiconductor compound are stacked. The layer including the p-type semiconductor compound and the layer including the n-type semiconductor compound may form a PN junction. Due to photoinduced charge separation that occurs at an interface of these layers, excitons may be efficiently separated into holes and electrons.

The p-type semiconductor compound may be a compound acting as an electron donor that supplies electrons. For example, the p-type semiconductor compound may be an organic compound having electron-donating properties. For example, the p-type semiconductor compound may include a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a naphthalocyanine compound, a cyanine compound, a melocyanine compound, an oxonol compound, a polyamine compound, an indole compound, a pyrrole compound, a pyrazole compound, a polyarylene compound, a condensed aromatic carbon ring compound (a naphthalene derivative, an anthracene derivative, a phenanthrene derivative, a tetracene derivative, a pyrene derivative, a perylene derivative, or a fluoranthene derivative) a metal complex having a nitrogen-containing heterocyclic compound as a ligand, and the like, but embodiments of the present invention are not limited thereto.

The n-type semiconductor compound may be a compound acting as an electron acceptor that accepts electrons. For example, the n-type semiconductor compound may be an organic compound having electron-accepting properties. For example, the n-type semiconductor compound may include fullerene, a fullerene derivative, a condensed aromatic carbon ring compound (a naphthalene derivative, an anthracene derivative, a phenanthrene derivative, a tetracene derivative, a pyrene derivative, a perylene derivative, or a fluoranthene derivative), a 5-membered to 7-membered heterocyclic compound containing a nitrogen atom, an oxygen atom, and a sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, tribenzazepine, etc.), a polyarylene compound, a fluorine compound, a cyclopentadiene compound, a silyl compound, a metal complex having a nitrogen-containing heterocyclic compound as a ligand, and the like, but embodiments of the present invention are not limited thereto.

Each of the first to third light-emitting devices ED1, ED2, and ED3 and the first light-receiving device PD1 may further include a charge auxiliary layer that facilitates movement of holes and electrons. The charge auxiliary layer may include the first common layer 221, the second common layer 222, the buffer layer, the third common layer 225, and the fourth common layer 226. The first common layer 221 and the second common layer 222 may be arranged between the pixel electrode 210 and the emission layer 223 and between the first sensing electrode 4210 and the first active layer 4223. The buffer layer, the third common layer 225, and the fourth common layer 226 may be arranged between the emission layer 223 and the counter electrode 230 and between the first active layer 4223 and the counter electrode 230. For example, each of the first to fourth common layers 221, 222, 225, and 226 and the buffer layer may be provided as a single body across the first to third light-emitting devices ED1, ED2, and ED3 and the first light-receiving device PD1.

In an embodiment of the present invention, a hole transport region may be defined between the pixel electrode 210 and the emission layer 223 and between the first sensing electrode 4210 and the first active layer 4223. In addition, an electron transport region may be provided between the emission layer 223 and the counter electrode 230 and between the first active layer 4223 and the counter electrode 230.

The hole transport region may facilitate movement of holes and may have a single-layer structure or a multi-layer structure. The hole transport region may include at least one of a hole injection layer (HIL), a hole transport layer (HTL), and an electron-blocking layer (EBL). In an embodiment of the present invention, the first common layer 221 arranged in the hole transport region may be an HIL, and the second common layer 222 arranged in the hole transport region may be an HTL.

For example, each of the first common layer 221 and the second common layer 222 may include at least one of m-MTDATA, TDATA, 2-TNATA, NPB (NPD), β-NPB, TPD, Spiro-TPD, Spiro-NPB, methylated-NPB, TAPC, HMTPD, 4,4′,4-tris(N-carbazolyl)triphenylamine (TCTA), polyaniline/dodecylbenzenesulfonic acid (Pani/DBSA), polyaniline/camphor sulfonic acid (Pani/CSA), poly(3,4-ethylenedioxythiophene)/poly(4-styrenesulfonate) (PEDOT/PSS), and/or polyaniline/poly(4-styrenesulfonate) (PANI/PSS).

The electron transport region may facilitate movement of electrons and may have a single-layer structure or a multi-layer structure. The electron transport region may include at least one of a buffer layer, an electron injection layer (EIL), an electron transport layer (ETL), and a hole-blocking layer (HBL). In an embodiment of the present invention, the third common layer 225 that is arranged in the electron transport region may be an ETL, and the fourth common layer 226 that is arranged in the electron transport region may be an EIL.

For example, the buffer layer may include an inorganic material, such as silicon oxide, silicon nitride, and/or silicon oxynitride, and each of the third common layer 225 and the fourth common layer 226 may include at least one of 2,9-dimethyl-4,7-diphenyl-1,10-phenanthroline (BCP), 4,7-diphenyl-1,10-phenanthroline (Bphen), Alq3, BAlq, 3-(biphenyl-4-yl)-5-(4-tert-butylphenyl)-4-phenyl-4H-1,2,4-triazole (TAZ), and/or NTAZ.

A capping layer 240 may be disposed on the first to third light-emitting devices ED1, ED2, and ED3 and the first light-receiving device PD1 having the structures as described above. For example, the capping layer 240 may be disposed on the counter electrode 230 and may be formed as a single body over the entire surface of the substrate 100. The capping layer 240 may prevent impurities, such as water and oxygen, from entering the display apparatus 1, thereby increasing the reliability of the display apparatus 1.

The capping layer 240 may be an organic capping layer including an organic material, an inorganic capping layer including an inorganic material, or an organic-inorganic composite capping layer including an organic material and an inorganic material. The capping layer 240 may include, for example, a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with substituents including, for example, O, N, S, Se, Si, F, Cl, Br, I, or any combination thereof.

In an embodiment of the present invention, the first upconversion device UCD1 may be disposed on the first light-receiving device PD1. As briefly described above, the first upconversion device UCD1 may absorb light having low energy, convert the absorbed light into light having high energy, and emit the converted light. For example, the first upconversion device UCD1 may absorb light having a long wavelength, convert the absorbed light into light having a short wavelength, and emit the converted light.

For example, the first upconversion device UCD1 may convert light in the near-infrared wavelength band into light in the visible light wavelength band and emit the converted light. The display apparatus 1 may emit light in the near-infrared wavelength band through the auxiliary light-emitting device ED4 (see FIG. 2A). The light in the near-infrared wavelength band emitted from the display apparatus 1 may be reflected by an object and then the reflected light may be incident on the first upconversion device UCD1 to be converted into light in the visible light wavelength band. When the first light-receiving device PD1 absorbs green light, the first upconversion device UCD1 may convert light in the near-infrared wavelength band into green light. However, embodiments of the present invention are not limited thereto, and when the first light-receiving device PD1 absorbs red light, the first upconversion device UCD1 may convert light in the near-infrared wavelength band into red light. In an embodiment of the present invention, the first upconversion device UCD1 may convert red light, which has a long wavelength among light in the visible light wavelength band, into green light, which has a relatively short wavelength.

Referring to FIGS. 5 and 6, the first upconversion device UCD1 may include a lower auxiliary electrode 510, an auxiliary intermediate layer 520, and an upper auxiliary electrode 530. Because the capping layer 240 is arranged between the first upconversion device UCD1 and the first light-receiving device PD1, the lower auxiliary electrode 510 may be disposed on the capping layer 240.

Each of the lower auxiliary electrode 510 and the upper auxiliary electrode 530 may be a semi-transmissive electrode or a transmissive electrode. For example, when each of the lower auxiliary electrode 510 and the upper auxiliary electrode 530 is a transmissive electrode, each of the lower auxiliary electrode 510 and the upper auxiliary electrode 530 may include a transparent conductive oxide (TCO) layer including ITO, IZO, ZnO, or In₂O₃. For example, when each of the lower auxiliary electrode 510 and the upper auxiliary electrode 530 is a semi-transmissive electrode, each of the lower auxiliary electrode 510 and the upper auxiliary electrode 530 may include a metal thin film including Li, Ca, LiF/Ca, LiF/Al, Al, Ag, Mg, and a compound thereof and having a small work function.

In an embodiment of the present invention, the lower auxiliary electrode 510 may be an electrode having a (−) electric potential, and the upper auxiliary electrode 530 may be an electrode having a (+) electric potential. However, embodiments of the present invention are not limited thereto, and in an embodiment of the present invention, the lower auxiliary electrode 510 may be an electrode having a (+) electric potential, and the upper auxiliary electrode 530 may be an electrode having a (−) electric potential. Each of the lower auxiliary electrode 510 and the upper auxiliary electrode 530 may be additionally connected to an auxiliary wire to have a corresponding electric potential. For example, the display apparatus 1 may include a first auxiliary wire connected to the lower auxiliary electrode 510 and a second auxiliary wire connected to the upper auxiliary electrode 530. The first auxiliary wire and the second auxiliary wire may connect the first upconversion device UCD1 to a pad that is arranged in the peripheral area PA (see FIG. 1). The first auxiliary wire and the second auxiliary wire may be extended by forming contact holes in a plurality of layers that are disposed below the first upconversion device UCD1. The first auxiliary wire and the second auxiliary wire may be configured to transmit electrical signals, which are output from the pad, to the lower auxiliary electrode 510 and the upper auxiliary electrode 530 to turn on and off the first upconversion device UCD1.

The auxiliary intermediate layer 520 may be arranged between the lower auxiliary electrode 510 and the upper auxiliary electrode 530. The auxiliary intermediate layer 520 may include an auxiliary emission layer 523 and an auxiliary active layer 527 disposed on the auxiliary emission layer 523. The auxiliary active layer 527 may absorb light in the near-infrared wavelength band that is reflected by an object and re-incident on the first upconversion device UCD1, and the auxiliary emission layer 523 may emit light in the visible light wavelength band.

In addition, the auxiliary intermediate layer 520 may further include a charge auxiliary layer that facilitates movement of holes and electrons. The auxiliary intermediate layer 520 may further include a first charge auxiliary layer 521 arranged between the lower auxiliary electrode 510 and the auxiliary emission layer 523. The auxiliary intermediate layer 520 may additionally include a second charge auxiliary layer 525 arranged between the auxiliary emission layer 523 and the auxiliary active layer 527, and a third charge auxiliary layer 529 arranged between the auxiliary active layer 527 and the upper auxiliary electrode 530.

First, when light in the near-infrared wavelength band is input to the first upconversion device UCD1, the auxiliary active layer 527 may generate excitons and then separate the generated excitons into holes and electrons. In an embodiment of the present invention, when a (−) electric potential is applied to the lower auxiliary electrode 510 and a (+) electric potential is applied to the upper auxiliary electrode 530, holes that are separated in the auxiliary active layer 527 may move toward the lower auxiliary electrode 510, and electrons that are separated in the auxiliary active layer 527 may move toward the upper auxiliary electrode 530. For example, the holes separated in the auxiliary active layer 527 may move toward the auxiliary emission layer 523. In this case, because the electrons may move from the lower auxiliary electrode 510 to the auxiliary emission layer 523, the holes and electrons may recombine in the auxiliary emission layer 523 to emit light in the visible light wavelength band.

When the lower auxiliary electrode 510 and the upper auxiliary electrode 530 have the electric potentials as described above, an electron transport region may be defined between the lower auxiliary electrode 510 and the auxiliary emission layer 523. For example, the first charge auxiliary layer 521 may include at least one of an EIL, an ETL, and an HBL. A hole transport region may be provided between the auxiliary emission layer 523 and the auxiliary active layer 527. For example, the second charge auxiliary layer 525 may be an HTL. An electron transport region may be provided between the auxiliary active layer 527 and the upper auxiliary electrode 530. For example, the third charge auxiliary layer 529 may include at least one of an EIL, an ETL, and an HBL.

In an embodiment of the present invention, when a (+) electric potential is applied to the lower auxiliary electrode 510 and a (−) electric potential is applied to the upper auxiliary electrode 530, electrons that are separated in the auxiliary active layer 527 may move toward the lower auxiliary electrode 510, and holes that are separated in the auxiliary active layer 527 may move toward the upper auxiliary electrode 530. For example, the electrons separated in the auxiliary active layer 527 may move toward the auxiliary emission layer 523. In this case, because the holes may move from the lower auxiliary electrode 510 to the auxiliary emission layer 523, the holes and electrons may recombine in the auxiliary emission layer 523 to emit light in the visible light wavelength band.

When the lower auxiliary electrode 510 and the upper auxiliary electrode 530 have the electric potentials as described above, a hole transport region may be provided between the lower auxiliary electrode 510 and the auxiliary emission layer 523. For example, the first charge auxiliary layer 521 may include at least one of an HIL, an HTL, and/or an EBL. An electron transport region may be provided between the auxiliary emission layer 523 and the auxiliary active layer 527. For example, the second charge auxiliary layer 525 may be an ETL. A hole transport region may be provided between the auxiliary active layer 527 and the upper auxiliary electrode 530. For example, the third charge auxiliary layer 529 may include at least one of an HIL, an HTL, and/or an EBL.

Like the emission layer 223 of the first to third light-emitting devices ED1, ED2, and ED3, the auxiliary emission layer 523 may include an organic material including a fluorescent or phosphorescent material that emits red, green, blue, or white light. The auxiliary emission layer 523 may be an organic emission layer including a low-molecular weight organic material or a polymer organic material. For example, the auxiliary emission layer 523 may be an organic emission layer and may include copper phthalocyanine, tris-8-hydroxyquinoline aluminum, a PPV-based material, a polyfluorene-based material, or tris(2-phenylpyridine)iridium (Ir(ppy)₃).

In an embodiment of the present invention, the auxiliary emission layer 523 may include a host material and a dopant material. The dopant material may be a material that emits light of a certain color and may include a light-emitting material. The light-emitting material may include at least one of a phosphorescent dopant, a fluorescent dopant, and/or a quantum dot. The host material may be a main material of the auxiliary emission layer 523 and may be a material that helps the dopant material to emit light.

Like the first active layer 4223 of the first light-receiving device PD1, the auxiliary active layer 527 may include a p-type semiconductor compound and an n-type semiconductor compound. The p-type semiconductor compound may be an organic compound having electron-donating properties, and the n-type semiconductor compound may be an organic compound having electron-accepting properties.

For example, the p-type semiconductor compound may include a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a naphthalocyanine compound, a cyanine compound, a melocyanine compound, an oxonol compound, a polyamine compound, an indole compound, a pyrrole compound, a pyrazole compound, a polyarylene compound, a condensed aromatic carbon ring compound (a naphthalene derivative, an anthracene derivative, a phenanthrene derivative, a tetracene derivative, a pyrene derivative, a perylene derivative, or a fluoranthene derivative) or a metal complex having a nitrogen-containing heterocyclic compound as a ligand, but embodiments of the present invention are not limited thereto.

For example, the n-type semiconductor compound may include fullerene, a fullerene derivative, a condensed aromatic carbon ring compound (a naphthalene derivative, an anthracene derivative, a phenanthrene derivative, a tetracene derivative, a pyrene derivative, a perylene derivative, or a fluoranthene derivative), a 5-membered to 7-membered heterocyclic compound containing a nitrogen atom, an oxygen atom, and a sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, tribenzazepine, etc.), a polyarylene compound, a fluorine compound, a cyclopentadiene compound, a silyl compound, or a metal complex having a nitrogen-containing heterocyclic compound as a ligand, but embodiments of the present invention are not limited thereto.

Accordingly, because the first upconversion device UCD1 having the structure as described above is disposed on the first light-receiving device PD1, the first light-receiving device PD1 may detect both light in the near-infrared wavelength band and light in the visible light wavelength band, and thus, the sensitivity of the optical sensor including the first light-receiving device PD1 may be increased. For example, when green light emitted from the first light-emitting device ED1 is reflected by an object and re-incident on the first light-receiving device PD1, the first light-receiving device PD1 may detect the re-incident light. In addition, when light in the near-infrared wavelength band emitted from the auxiliary light-emitting device ED4 (see FIG. 2A) is reflected by on object and re-incident on the first upconversion device UCD1, the re-incident light may be converted into green light through the first upconversion device UCD1, and the first light-receiving device PD1 may detect the converted light. Accordingly, the display apparatus 1 including the first upconversion device UCD1 may sense not only fingerprint information by using light in the visible light wavelength band, but also biometric information using light in the near-infrared wavelength band.

In addition, the transmittance of the first upconversion device UCD1 itself may be determined using the thickness of each of layers included in the first upconversion device UCD1 or an interfacial refractive index difference between the layers. In this case, when the transmittance of the first upconversion device UCD1 is high, a relatively greater amount of light in the visible light wavelength band may pass through the first upconversion device UCD1, and thus, the sensing sensitivity of the first light-receiving device PD1 to light in the visible light wavelength band may increase. In addition, when the transmittance of the first upconversion device UCD1 is low, a relatively greater amount of light in the near-infrared wavelength band may be converted through the first upconversion device UCD1, and thus, the sensing sensitivity of the first light-receiving device PD1 to light in the near-infrared wavelength band may increase. As such, by changing the transmittance of the first upconversion device UCD1, the sensing sensitivity of the first light-receiving device PD1 to each of light in the near-infrared wavelength band and light in the visible light wavelength band may be adjusted, as necessary.

Referring back to FIG. 5, a thin-film encapsulation layer 300 may be disposed on the plurality of light-emitting devices and the plurality of light-receiving devices. In the display apparatus 1 according to an embodiment of the present invention, because the first upconversion device UCD1 is disposed on the first light-receiving device PD1, the thin-film encapsulation layer 300 may be disposed on the first upconversion device UCD1. For example, the thin-film encapsulation layer 300 may be disposed on the capping layer 240 and the upper auxiliary electrode 530.

The thin-film encapsulation layer 300 may include at least one inorganic encapsulation layer and at least one organic encapsulation layer. In an embodiment of the present invention, FIG. 5 shows that the thin-film encapsulation layer 300 includes a first inorganic encapsulation layer 310, an organic encapsulation layer 320, and a second inorganic encapsulation layer 330, which are sequentially stacked on each other.

For example, each of the first inorganic encapsulation layer 310 and the second inorganic encapsulation layer 330 may include one or more inorganic materials from among aluminum oxide, titanium oxide, tantalum oxide, hafnium oxide, zinc oxide, silicon oxide, silicon nitride, and silicon oxynitride. For example, the organic encapsulation layer 320 may include a polymer-based material. The polymer-based material may include acrylic resin, epoxy-based resin, polyimide, and polyethylene. In an embodiment of the present invention, the organic encapsulation layer 320 may include acrylate. The organic encapsulation layer 320 may be formed by curing a monomer or applying a polymer. The organic encapsulation layer 320 may have transparency.

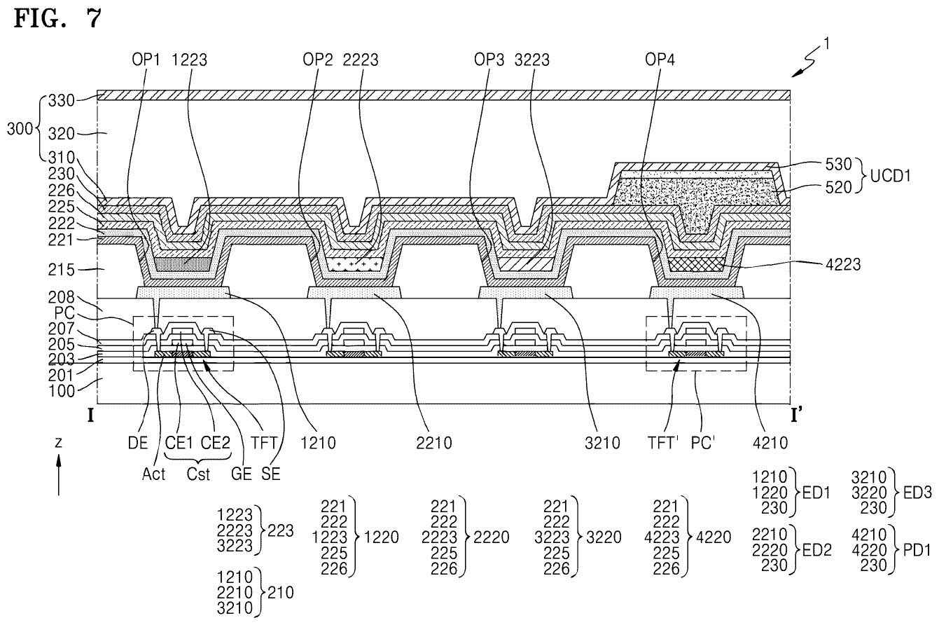

FIG. 7 is a schematic cross-sectional view of a portion of the display apparatus 1 according to an embodiment of the present invention. Referring to FIG. 7, except for the characteristics (e.g., elements and components) of the first upconversion device UCD1, other characteristics (e.g., elements and components) are the same as those described with reference to FIGS. 5 and 6. Among the elements of FIG. 7, elements that are the same as those described above with reference to FIGS. 5 and 6 may use the same reference numerals as used in FIGS. 5 and 6, and differences are mainly described below, while redundant descriptions may be omitted or briefly discussed.

Referring to FIG. 7, the first upconversion device UCD1 may be disposed on the first light-receiving device PD1. In this case, the first upconversion device UCD1 and the first light-receiving device PD1 may be arranged in direct contact with each other. In other words, the capping layer 240 (see FIG. 5) might not be arranged between the first upconversion device UCD1 and the first light-receiving device PD1. The first upconversion device UCD1 may be arranged in contact with an upper surface of the counter electrode 230.

The first upconversion device UCD1 may include the auxiliary intermediate layer 520 and the upper auxiliary electrode 530. As described above, the auxiliary intermediate layer 520 may include the auxiliary emission layer 523 (see FIG. 6) and the auxiliary active layer 527 (see FIG. 6). In addition, the auxiliary intermediate layer 520 may further include the first charge auxiliary layer 521 (see FIG. 6), the second charge auxiliary layer 525 (see FIG. 6), and the third charge auxiliary layer 529 (see FIG. 6), which facilitate movement of holes and electrons.

However, in the display apparatus 1 shown in FIG. 7, the first upconversion device UCD1 might not include the lower auxiliary electrode 510 (see FIG. 5). Instead, the first upconversion device UCD1 may use the counter electrode 230 of the first light-receiving device PD1 as the lower auxiliary electrode 510 (see FIG. 5). In other words, the counter electrode 230 may be commonly used in the first light-receiving device PD1 and the first upconversion device UCD1.

When light in the near-infrared wavelength band is input to the first upconversion device UCD1, the auxiliary active layer 527 may generate excitons and then separate the generated excitons into holes and electrons. In an embodiment of the present invention, when a (−) electric potential is applied to the counter electrode 230 and a (+) electric potential is applied to the upper auxiliary electrode 530, holes that are separated in the auxiliary active layer 527 may move toward the counter electrode 230, and electrons that are separated in the auxiliary active layer 527 may move toward the upper auxiliary electrode 530. For example, the holes that are separated in the auxiliary active layer 527 may move toward the auxiliary emission layer 523. In this case, because the electrons may move from the counter electrode 230 to the auxiliary emission layer 523, the holes and electrons may recombine in the auxiliary emission layer 523 to emit light in the visible light wavelength band.

Accordingly, because the first upconversion device UCD1 having the structure as described above is disposed on the first light-receiving device PD1, the first light-receiving device PD1 may detect both light in the near-infrared wavelength band and light in the visible light wavelength band, and thus, the sensitivity of the optical sensor including the first light-receiving device PD1 may be increased. For example, when green light emitted from the first light-emitting device ED1 is reflected by an object and re-incident on the first light-receiving device PD1, the first light-receiving device PD1 may detect the re-incident light. In addition, when light in the near-infrared wavelength band that is emitted from the auxiliary light-emitting device ED4 (see FIG. 2A) is reflected by an object and re-incident on the first upconversion device UCD1, the re-incident light may be converted into green light through the first upconversion device UCD1, and the first light-receiving device PD1 may detect the converted light. Accordingly, the display apparatus 1 including the first upconversion device UCD1 may sense not only fingerprint information by using light in the visible light wavelength band, but also biometric information by using light in the near-infrared wavelength band.

The display apparatus according to the embodiment may be applied to various electronic apparatuses. An electronic apparatus according to an embodiment of the present disclosure may include the display apparatus (e.g., the display apparatus of FIG. 1) described above, and may further include modules or apparatuses having additional functions in addition to the display apparatus.

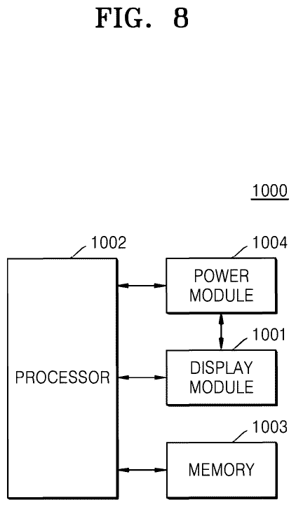

FIG. 8 is a block diagram of an electronic apparatus according to an embodiment.

Referring to FIG. 8, an electronic apparatus 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic apparatus 1000.

At least one of the components of the electronic apparatus 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic apparatus 1000 except for the display apparatus.

In an embodiment, the display module 1001 included in the display apparatus may drive based on the image data signal and the input control signal received from the processor 1002.

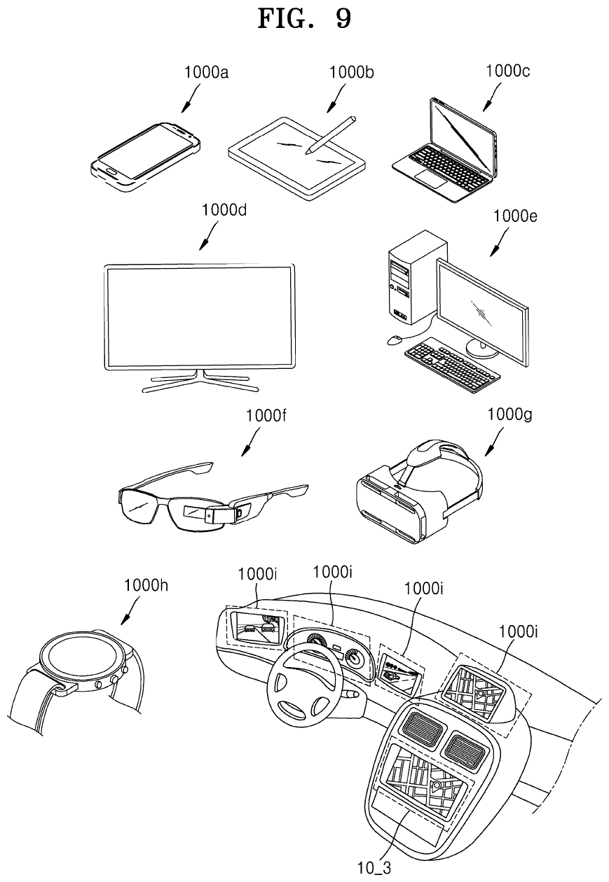

FIG. 9 is schematic diagrams of electronic apparatuses according to various embodiments.

Referring to FIG. 9, various electronic apparatuses to which display apparatuses according to embodiments are applied may include not only image display electronic apparatuses such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

In a display apparatus according to an embodiment of the present invention as described above, the sensing sensitivity of a light-receiving device may be increased. However, the above effect is only an example, and the scope of the present invention is not limited thereto.

While the present invention has been described with reference to exemplary embodiments thereof, it will be understood by those of ordinary skill in the art that various changes in form and details may be made thereto without departing from the spirit and scope of the present invention.

What is claimed is:

1. A display apparatus comprising:
a substrate comprising an emission area and a sensing area;
a light-emitting device disposed on the substrate to correspond to the emission area;
a light-receiving device disposed on the substrate to correspond to the sensing area; and
an upconversion device covering the light-receiving device.

2. The display apparatus of claim 1, wherein the upconversion device is configured to convert light in a first wavelength band into light in a second wavelength band and emit the converted light, wherein the upconversion device is configured to receive the light in the first wavelength band from outside, and
the light in the second wavelength band has a shorter wavelength than the light in the first wavelength band.

3. The display apparatus of claim 2, wherein the upconversion device is further configured to convert light in a near-infrared wavelength band into light in a visible light wavelength band and emit the converted light, wherein the upconversion device is configured to receive the light in the near-infrared wavelength band from the outside.

4. The display apparatus of claim 1, wherein the light-receiving device comprises:
a sensing electrode;
an active layer disposed on the sensing electrode; and
a counter electrode disposed on the active layer.

5. The display apparatus of claim 4, wherein the light-emitting device comprises:
a pixel electrode;
an emission layer disposed on the pixel electrode; and
a counter electrode disposed on the emission layer.

6. The display apparatus of claim 5, wherein the counter electrode of the light-receiving device and the counter electrode of the light-emitting device are formed as a single body on the substrate.

7. The display apparatus of claim 4, wherein the upconversion device comprises:
a lower auxiliary electrode disposed on the counter electrode;
an auxiliary intermediate layer disposed on the lower auxiliary electrode; and
an upper auxiliary electrode disposed on the auxiliary intermediate layer.

8. The display apparatus of claim 7, wherein the auxiliary intermediate layer comprises:
an auxiliary emission layer disposed on the lower auxiliary electrode; and
an auxiliary active layer disposed on the auxiliary emission layer.

9. The display apparatus of claim 7, further comprising a capping layer that is arranged between the counter electrode and the lower auxiliary electrode.

10. The display apparatus of claim 4, wherein the upconversion device comprises:
an auxiliary intermediate layer disposed on the counter electrode; and
an upper auxiliary electrode disposed on the auxiliary intermediate layer.

11. The display apparatus of claim 10, wherein the auxiliary intermediate layer comprises:
an auxiliary emission layer disposed on the counter electrode; and
an auxiliary active layer disposed on the auxiliary emission layer.

12. The display apparatus of claim 10, wherein an upper surface of the counter electrode and a lower surface of the auxiliary intermediate layer are in contact with each other.

13. The display apparatus of claim 12, wherein the counter electrode of the light-receiving device is also used as a lower auxiliary electrode of the upconversion device.

14. The display apparatus of claim 1, further comprising a thin-film encapsulation layer disposed on the light-emitting device and the upconversion device.

15. A display apparatus comprising:
a substrate;
a light-emitting device disposed on the substrate and comprising a pixel electrode, an emission layer disposed on the pixel electrode, and a counter electrode disposed on the emission layer;
a light-receiving device disposed on the substrate and comprising a sensing electrode, an active layer disposed on the sensing electrode, and a counter electrode disposed on the active layer; and
an upconversion device overlapping the light-receiving device and comprising an auxiliary intermediate layer and an upper auxiliary electrode disposed on the auxiliary intermediate layer.

16. The display apparatus of claim 15, wherein the upconversion device is configured to convert light in a first wavelength band into light in a second wavelength band and emit the converted light, wherein the upconversion device is configured to receive the light in the first wavelength band from outside, and
the light in the second wavelength band has a shorter wavelength than the light in the first wavelength band.

17. The display apparatus of claim 15, wherein the auxiliary intermediate layer comprises:
an auxiliary emission layer disposed on the light-receiving device; and
an auxiliary active layer disposed on the auxiliary emission layer.

18. The display apparatus of claim 15, wherein the upconversion device further comprises a lower auxiliary electrode that is arranged between the counter electrode of the light-receiving device and the auxiliary intermediate layer.

19. The display apparatus of claim 18, further comprising a capping layer that is arranged between the counter electrode of the light-receiving device and the lower auxiliary electrode.

20. The display apparatus of claim 15, wherein an upper surface of the counter electrode of the light-receiving device and a lower surface of the auxiliary intermediate layer are in contact with each other.

21. The display apparatus of claim 20, wherein the counter electrode of the light-receiving device is commonly used in the light-receiving device and the upconversion device.

22. An electronic apparatus comprising a display apparatus,
Wherein the display apparatus comprises:
a substrate comprising an emission area and a sensing area;
a light-emitting device disposed on the substrate to correspond to the emission area;
a light-receiving device disposed on the substrate to correspond to the sensing area; and
an upconversion device covering the light-receiving device.

23. The electronic apparatus of claim 22, further comprising:
a display module;
a processor;
a power module; and
a memory,
wherein the display apparatus includes one of the display module, the processor, the power module, or the memory.
